(19) United States
(12) Patent Application Publication
(10) Pub. No.: US 2025/0379186 A1
(43) Pub. Date: Dec. 11, 2025

(54) SEMICONDUCTOR PACKAGE HAVING A SEMICONDUCTOR DIE LAYER

(71) Applicant: Sandisk Technologies, Inc., Milpitas, CA (US)

(72) Inventors: Fei Wang, Shanghai (CN); Hui Xu, Shanghai (CN); Teng Sun, Shanghai (CN); Gang Liu, Shanghai (CN); Tan Chong Un, Shanghai (CN)

(21) Appl. No.: 18/735,529

(22) Filed: Jun. 6, 2024

(51) Int. Cl. H01L 25/065; H01L 21/48; H01L 23/00; H01L 23/498; H01L 25/16

(52) U.S. Cl. CPC H01L 25/0652; H01L 21/4846; H01L 23/49811; H01L 24/13; H01L 24/16; H01L 24/24; H01L 24/29; H01L 24/32; H01L 24/73; H01L 24/83; H01L 25/16; H01L 2224/13147; H01L 2224/16145; H01L 2224/16225; H01L 2224/24137; H01L 2224/24226; H01L 2224/2919; H01L 2224/32137; H01L 2224/73209; H01L 2224/73253; H01L 2224/73267; H01L 2224/83005; H01L 2224/83855; H01L 2924/1438

(57) ABSTRACT

A semiconductor die layer for a semiconductor package includes a first semiconductor die and a second semiconductor die adjacent the first semiconductor die. The first and second semiconductor dies are joined together by a filling material located between the dies. First and second RDLs are provided on first and second surfaces of the semiconductor die layer. Each RDL includes traces that enable the first semiconductor die to be directly coupled to the second semiconductor die, thereby eliminating the need for a silicon interposer. Vias are provided in the filling material and enable vertical communication between different semiconductor die layers that are included in the semiconductor package. Solder balls are provided on the second RDL and enable a semiconductor die layer to be directly coupled to a PCB or another semiconductor die layer.

### BACKGROUND

Semiconductor packages today utilize either 2.5D packaging technology or 3D packaging technology. In a 2.5D semiconductor package, two or more integrated circuits and/or semiconductor dies are placed side by side on a silicon interposer. The silicon interposer acts as a bridge between the dies and a substrate. Typically, a redistribution layer (RDL) is formed on the silicon interposer to enable high-density interconnections between the integrated circuits and/or the semiconductor dies. The silicon interposer also includes through-silicon vias (TSVs) that route signals between the integrated circuits and/or the semiconductor dies and the substrate.

In a 3D semiconductor package, two or more semiconductor dies are vertically stacked on top of each other. Typically, the semiconductor dies are interconnected using TSVs. The TSVs extend through each semiconductor die and enable the semiconductor dies in the stack to communicate with each other.

However, each packaging technology has its drawbacks. For example, in a 2.5D semiconductor package, the integrated circuits and/or the semiconductor dies are not directly connected to each other and must rely on the silicon interposer (i.e., the RDL on the interposer) for communications. In a 3D semiconductor package, the semiconductor dies can only be vertically connected (e.g., in the Z-axis). Typically, the Z-height of a semiconductor package is limited by height constraints. As such, the 3D semiconductor package can only have a particular number of semiconductor dies stacked on top of one another, which limits the capabilities of the 3D semiconductor package.

Accordingly, it would be advantageous to increase the capabilities of a semiconductor package without relying on a silicon interposer for interconnections and/or being limited by semiconductor package Z-height constraints.

### SUMMARY

The present application describes a semiconductor package that includes at least one semiconductor die layer. In an example, the semiconductor die layer includes at least a first semiconductor die and a second semiconductor die adjacent to the first semiconductor die. The first semiconductor die and the second semiconductor die are joined together using a filling material such as, for example, an epoxy filler.

The semiconductor die layer also includes a first redistribution layer (RDL) on a first surface (e.g., a top surface) and a second RDL on a second surface (e.g., a bottom surface) opposite the first surface. In an example, the RDL layers include traces or other communication means that directly couple the first semiconductor die to the second semiconductor die, thereby eliminating the need for a silicon interposer.

Additionally, one or more vias are provided in the filling material. The vias enable vertical communication between different semiconductor die layers that are included in a semiconductor package. The vias also enable communication between one or more of the semiconductor die layers and a printed circuit board (PCB) on which a stack of semiconductor die layers are coupled.

One or more solder balls, for example, are provided on or are otherwise associated with the second RDL of each semiconductor die layer. The solder balls enable one semiconductor die layer to be stacked on top of another semiconductor die layer. The solder balls also enable the semiconductor die layer(s) to be electrically and/or communicatively coupled to the PCB.

Accordingly, examples of the present disclosure describe a semiconductor package that includes a first semiconductor die and a second semiconductor die adjacent to the first semiconductor die. A filling material is provided between the first semiconductor die and the second semiconductor die. The filling material joints a first lateral side of the first semiconductor die to a second lateral side of the second semiconductor die. A first RDL is formed on top surfaces of the first semiconductor die and the second semiconductor die and a second RDL formed on bottom surfaces of the first semiconductor die and the second semiconductor die.

Other examples describe a semiconductor package that includes a first semiconductor die layer and a second semiconductor die layer stacked on top of the first semiconductor die layer. In an example, the first semiconductor die layer includes a first semiconductor die adjacent a second semiconductor die and joined to the second semiconductor die by a first filling material. A first RDL is formed on first surfaces of the first semiconductor die and the second semiconductor die and a second RDL is formed on second surfaces of the first semiconductor die and the second semiconductor die. The second semiconductor die layer includes a third semiconductor die adjacent a fourth semiconductor die. The third semiconductor die is joined to the fourth semiconductor die by a second filling material. A third RDL is formed on first surfaces of the third semiconductor die and the fourth semiconductor die and a fourth RDL is formed on second surfaces of the third semiconductor die and the fourth semiconductor die.

Another example of the present disclosure describes a method for assembling a semiconductor die layer for a semiconductor package. In an example, the method includes placing a plurality of semiconductor dies side-by-side on a carrier and causing a filling material to flow between each of the plurality of semiconductor dies. The filling material is cured to join each of the plurality of semiconductor dies to at least one other semiconductor die of the plurality of semiconductor dies. The joined semiconductor dies are removed from the carrier and one or more vias are formed in the filling material between each of the plurality of semiconductor dies.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a semiconductor package that utilizes current packaging solutions according to an example.

FIG. 2 illustrates a semiconductor die layer for a semiconductor package according to an example.

FIG. 3 illustrates a cross-section view of the semiconductor die layer of FIG. 2 according to an example.

FIG. 4 illustrates a top view of the semiconductor die layer of FIG. 2 according to an example.

FIG. 5 illustrates a bottom view of the semiconductor die layer of FIG. 2 according to an example.

FIG. 6 illustrates a semiconductor package having a multiple semiconductor die layers according to an example.

FIG. 7 illustrates a semiconductor package having multiple semiconductor die layers according to another example.

FIG. 8 depicts a method of creating a semiconductor die layer for a semiconductor package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

Today, the prevalent packaging technologies for semiconductor packages are 2.5D packaging technology and 3D packaging technology. In a 2.5D semiconductor package, two or more integrated circuits or two or more semiconductor dies are placed side by side on a silicon interposer. The silicon interposer acts as a bridge between the dies and a substrate. Typically, a redistribution layer (RDL) is formed on the silicon interposer to enable high-density interconnections between the integrated circuits and/or the semiconductor dies. The silicon interposer also includes through-silicon vias (TSVs) that route signals between the integrated circuits and/or the semiconductor dies and the substrate.

In a 3D semiconductor package, two or more semiconductor dies are vertically stacked on top of each other. Typically, the semiconductor dies are interconnected using TSVs. The TSVs extend through each semiconductor die and enable the semiconductor dies in the stack to communicate with each other.

However, in a 2.5D semiconductor package, the integrated circuits and/or the semiconductor dies cannot be directly connected to each other and must rely on the silicon interposer for communication. In a 3D semiconductor package, the semiconductor dies can only be vertically connected (e.g., in the Z-axis) which limits the connectivity to other semiconductor dies.

To address the above, the present application describes a semiconductor package having a least one semiconductor die layer. In an example, the semiconductor die layer includes at least a first semiconductor die and a second semiconductor die adjacent to the first semiconductor die. The first semiconductor die and the second semiconductor die are joined together using a filling material. A first redistribution layer (RDL) is provided on a first surface (e.g., a top surface of each semiconductor die) of the semiconductor die layer and a second RDL is provided on a second surface (e.g., a bottom surface of each semiconductor die) of the semiconductor die layer opposite the first surface. Each of the first RDL and the second RDL include traces or other communication pathways that directly couple the first semiconductor die to the second semiconductor die, thereby eliminating the need for a silicon interposer.

Additionally, one or more vias are formed in the filling material. The vias enable vertical communication between different semiconductor die layers that are included in a semiconductor package. The vias also enable communication between one or more of the semiconductor die layers and a printed circuit board (PCB) on which a stack of semiconductor die layers are coupled.

For example, one or more solder balls are provided on or are otherwise associated with the second RDL of each semiconductor die layer. The solder balls enable one semiconductor die layer to be stacked on top of another semiconductor die layer. The solder balls also enable the semiconductor die layer(s) to be electrically and/or communicatively coupled to the PCB (e.g., without the need for a substrate).

Accordingly, many technical benefits may be realized including, but not limited to, enabling integrated circuits and/or semiconductor dies to be directly connected in the X, Y and Z planes, eliminating the need for an interposer and the substrate which reduces the Z-height of the semiconductor package, and improving semiconductor die integration density.

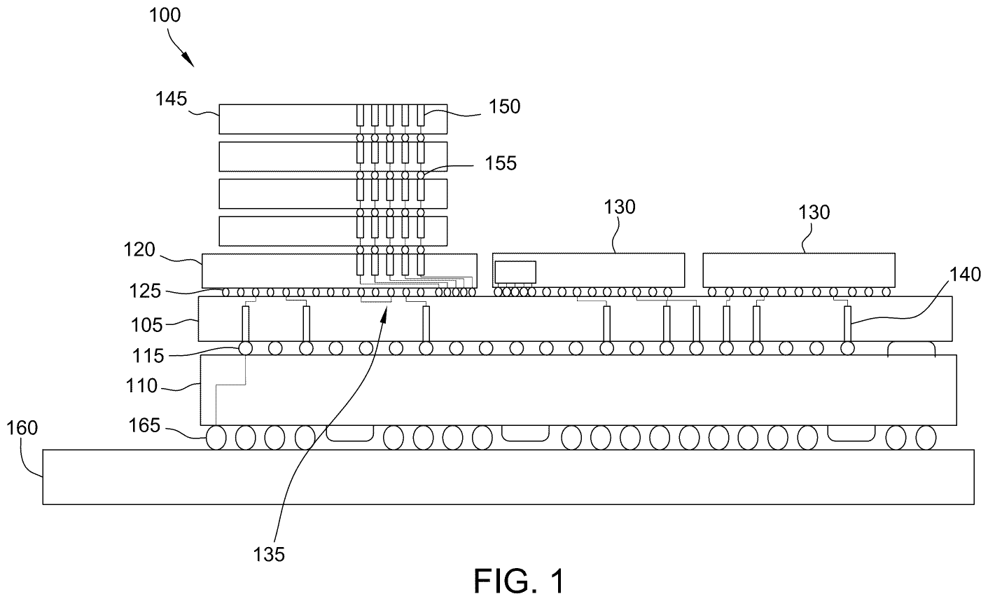

These and other examples will be described in more detail with respect to FIG. 1-FIG. 8.

FIG. 1 illustrates a semiconductor package 100 that utilizes current packaging solutions according to an example. In the example shown, the semiconductor package 100 includes an interposer 105 electrically coupled to a substrate 110. In an example, the interposer 105 is electrically coupled to the substrate 110 using various connection points 115 (e.g., copper bumps).

In current solutions, the interposer 105 enables multiple semiconductor dies to be placed side by side and communicate with each other. For example, a semiconductor die 120 and additional semiconductor dies 130 (e.g., logic semiconductor dies) are mounted, side by side, on a top surface of the silicon interposer 105 using a plurality of micro bumps 125. Various wires 135 that are part of a redistribution layer are/or vias 140 are used to interconnect to the semiconductor die 120 and the additional semiconductor dies 130.

The semiconductor package 100 also includes memory dies 145. In this example, the memory dies 145 are vertically stacked on the semiconductor die 120. Various vias 150 and bumps 155 are used to couple the memory dies 145 to each other and/or to the semiconductor die 120.

In an example, the semiconductor package 100 is electrically and/or communicatively coupled to a printed circuit board (PCB) 160. For example, various solder balls 165 on a bottom surface of the substrate 110 are used to electrically couple the semiconductor package 100 to the PCB 160.

However, as previously described, one drawback with the current solution shown and described with respect to FIG. 1, is that the various semiconductor dies are reliant on the interposer 105 and the substrate 110 for interconnections. For example, the semiconductor dies cannot be directly connected to each other (e.g., the interposer 105 and/or the substrate 110 provide the medium through which the semiconductor dies are connected). Additionally, the semiconductor dies cannot be directly coupled to the PCB 160. Rather, the substrate 110 enables the semiconductor dies to be coupled to the PCB 160. In addition to limiting the connection paths between the various components, inclusion of the interposer 105 and the substrate 110 increases the Z-height of the semiconductor package 100 (especially when compared with the features of the present disclosure).

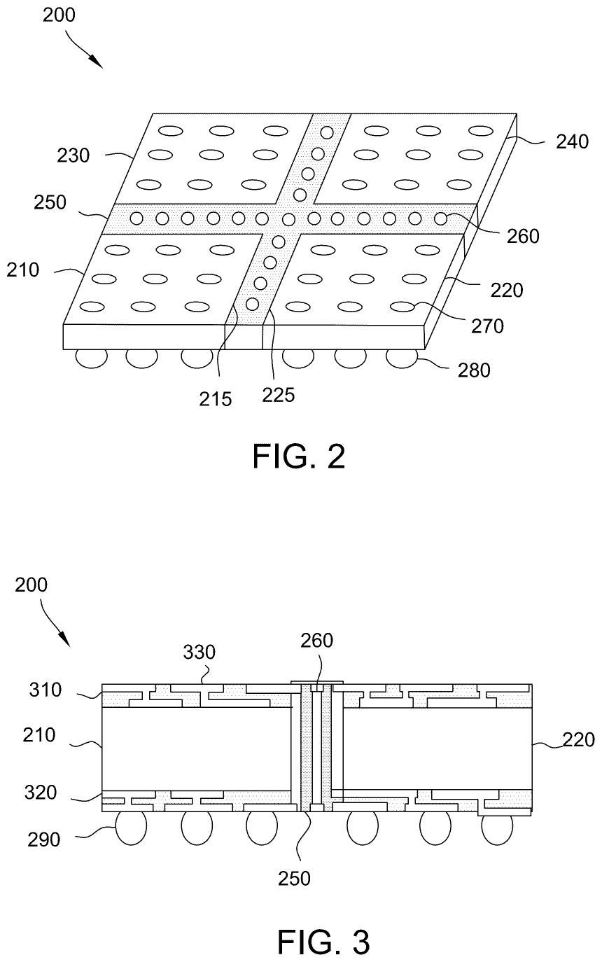

FIG. 2 illustrates semiconductor die layer 200 for a semiconductor package according to an example. Although FIG. 2 illustrates a single semiconductor die layer 200, other figures shown and described herein will illustrate the semiconductor die layer 200 being included, along with other semiconductor die layers, in a semiconductor package.

In an example, the semiconductor die layer 200 includes multiple semiconductor dies. For example, the semiconductor die layer 200 includes a first semiconductor die 210, a second semiconductor die 220, a third semiconductor die 230 and a fourth semiconductor die 240. Although four semiconductor dies are shown and described, the semiconductor die layer 200 can include fewer than four semiconductor dies or more than four semiconductor dies.

Each semiconductor die of the semiconductor die layer 200 is placed or positioned adjacent or next to at least one other semiconductor die (e.g., on the same plane) such that at least a first lateral side of one semiconductor die is adjacent to at least a first lateral side of another semiconductor die. For example, the first semiconductor die 210 is positioned adjacent to the second semiconductor die 220. As such, a first lateral side 215 of the first semiconductor die 210 is adjacent to a first lateral side 225 of the second semiconductor die 220.

In the example shown, and because the semiconductor die layer 200 includes four semiconductor dies, the first semiconductor die 210 is also positioned adjacent the third semiconductor die 230. Additionally, the third semiconductor die 230 is positioned adjacent the fourth semiconductor die 240 and the fourth semiconductor die 240 is positioned adjacent the second semiconductor die 220 forming a 2×2 semiconductor die layer 200. As such various lateral sides of each of the semiconductor dies are placed next to or adjacent other lateral sides of the other semiconductor dies.

Although the semiconductor die layer 200 is shown in a 2×2 arrangement, the semiconductor die layer 200 may have any configuration and/or any number of semiconductor dies. For example, if the semiconductor die layer 200 includes six semiconductor dies, the semiconductor dies could be arranged in a 2×3 layout, a 3×2 layout, a 1×6 layout or a 6×1 layout.

In an example, each semiconductor die in the semiconductor die layer 200 is the same type of semiconductor die. For example, each of the first semiconductor die 210, the second semiconductor die 220, the third semiconductor die 230 and the fourth semiconductor die 240 are memory dies (e.g., NAND memory dies).

In another example, at least one semiconductor die in the semiconductor die layer 200 is a different type of semiconductor die than at least one other semiconductor die in the semiconductor die layer 200. For example, the first semiconductor die 210 is a first type of semiconductor die (e.g., a control die) and the second semiconductor die 220, the third semiconductor die 230 and the fourth semiconductor die 240 are a second type of semiconductor die (e.g., a memory die).

Each semiconductor die in the semiconductor die layer 200 is joined to at least one other semiconductor die using a filling material 250. For example, a filling material is provided between lateral sides of each semiconductor die to join the semiconductor dies together. In an example, the filling material 250 is an epoxy filling material. Although an epoxy filling material is described, the filling material 250 can be any type of material.

In an example, one or more vias 260 are provided, or are otherwise formed in, the filling material 250. The vias 260 may be arranged in any pattern. Additionally, the vias may have any depth. For example, some vias extend entirely though the filling material 250 while others extend partially through the filling material 250.

The vias 260 enable various traces or other communications/signals means to pass from a first area or location on the semiconductor die layer 200 to a second area or location on the semiconductor die layer. In another example, the vias 260 enable multiple semiconductor die layers to be directly coupled to each other.

The semiconductor die layer 200 also includes a first redistribution layer (RDL) (e.g., RDL 310 (FIG. 3)) on a first surface (e.g., a top surface) of each semiconductor die and a second RDL (e.g., RDL 320) on a second surface (e.g., a bottom surface) of each semiconductor die. In an example, the RDL layers extend entirely across the surfaces of the semiconductor dies and/or the semiconductor die layer 200. For example, the first RDL extends across the first surface of the first semiconductor die 210, the second semiconductor die 220, the third semiconductor die 230, the fourth semiconductor die 240 and the filling material 250. In another example, the first RDL only extends across each semiconductor die. In yet another example, the first RDL extends partially across one or more of the semiconductor dies.

Each of the first RDL, the second RDL and/or the vias 260 enable the semiconductor dies to be directly connected to each other (e.g., without the use of an interposer). For example, each semiconductor die includes one or more bond pads 270 or solder pads on a top surface and/or a bottom surface. The bond pads enable communications between the first and second semiconductor dies and the first RDL. For example, when the RDL layer is formed on the top and/or bottom surfaces of the semiconductor die layer 200, traces of each RDL are coupled to respective bond pads 270.

In an example, each semiconductor die in the semiconductor die layer 200 is directly electrically and/or communicatively coupled to at least one other semiconductor die of the semiconductor die layer 200. For example, the first semiconductor die 210 is directly electrically coupled (e.g., in the X axis and/or Y axis) to the second semiconductor die 220, the third semiconductor die 230 and/or the fourth semiconductor die 240. Additionally, the vias 260 enable the first RDL to be communicatively coupled to the second RDL (and vice versa).

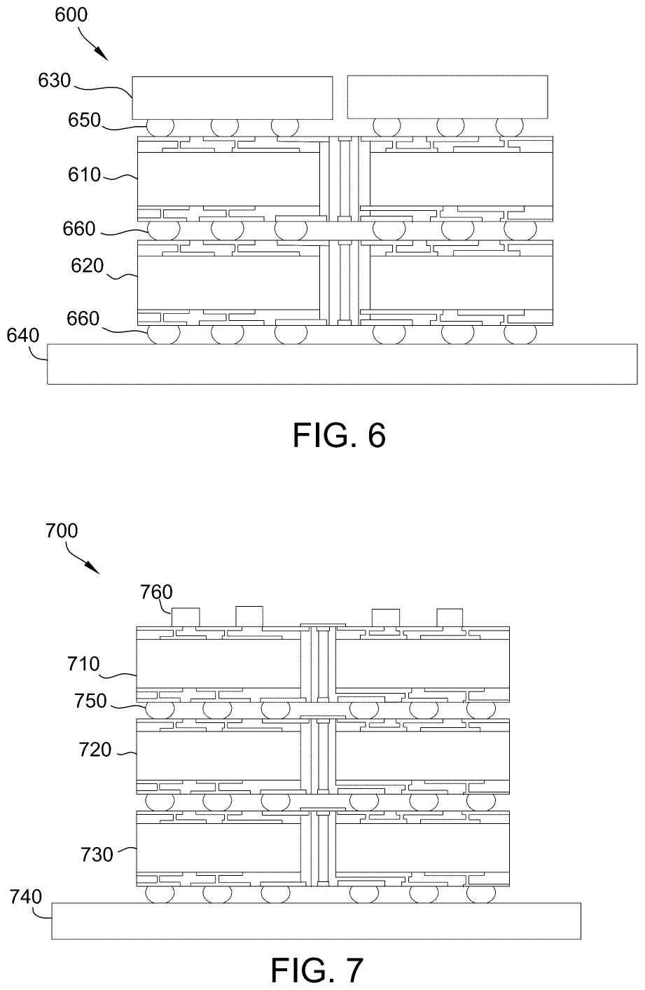

In an example, the semiconductor die layer 200 also includes one or more connection points 280 provided on a bottom surface of one or more of the semiconductor dies. In an example, the connection points 280 are solder balls. In another example, the connection points 290 are copper bumps. The connection points 280 are provided on or over the second RDL and/or are connected to various traces associated with the first RDL, the second RDL and/or the vias 260. In an example, the connection points 280 enable the semiconductor die layer 200 to be directly coupled to a printed circuit board (PCB) (e.g., without using a substrate). Additionally, the connection points 280 enable multiple semiconductor die layers to be stacked on top of one another as will be shown in greater detail with respect to FIG. 6 and FIG. 7.

FIG. 3 illustrates a cross-section view of the semiconductor die layer 200 of FIG. 2 according to an example. As shown in FIG. 3, the semiconductor die layer 200 includes a first semiconductor die 210 and a second semiconductor die 220. Additionally, the first semiconductor die 210 is joined together with the second semiconductor die 220 using a filling material 250. One or more vias 260 are formed in the filling material 250. In an example, the vias 260 extend completely though the filling material 250. In another example, the vias extend partially though the filling material 250.

A first RDL 310 is provided on a first surface of the first semiconductor die 210 and the second semiconductor die 220. Likewise, a second RDL 320 is provided on a second surface of the first semiconductor die 210 and the second semiconductor die 220. Each of the first RDL 310 and the second RDL 320 include various traces 330 or other communication/signaling means that enable the first semiconductor die 210 to be directly coupled to the second semiconductor die 220 and vice versa. Additionally, the traces 330 extend through the vias 260 provided in the filling material 250 which enables the first RDL 310 to be electrically coupled to the second RDL 320 and/or to the one or more connection points 280 provided on the second RDL 320.

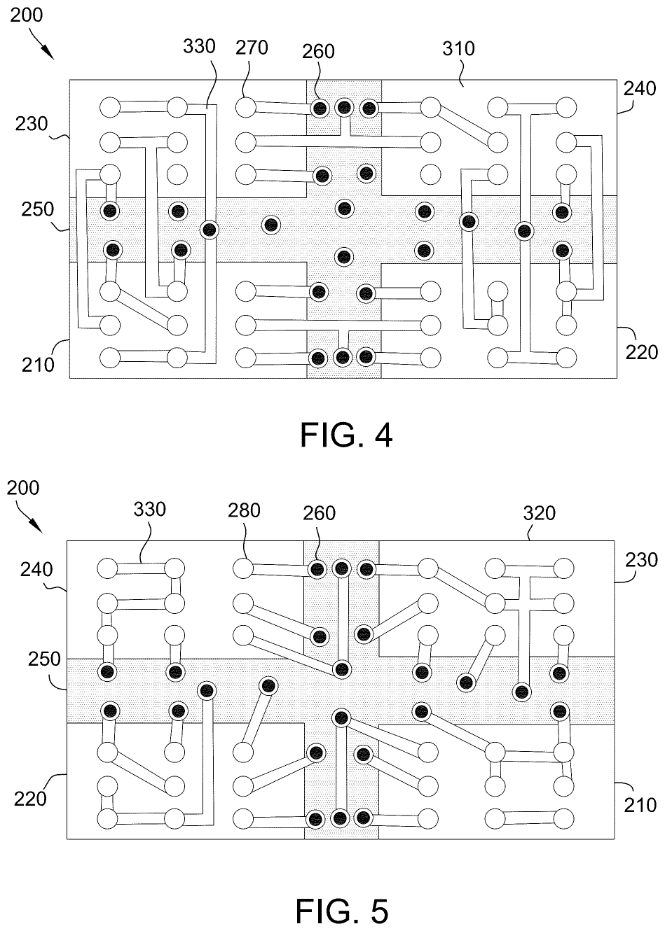

FIG. 4 illustrates a top view of the semiconductor die layer 200 of FIG. 2 according to an example. As previously explained, the semiconductor die layer 200 includes a first semiconductor die 210, a second semiconductor die 220, a third semiconductor die 230 and a fourth semiconductor die 240. Each semiconductor die is placed adjacent to at least one other semiconductor die and a filling material 250 joins the semiconductor dies together (e.g., on lateral sides). One or more vias 260 are formed in the filling material 250 such as previously described.

A first RDL 310 is provided on or over a first surface (or a top surface) of each semiconductor die. In an example and as previously discussed, the first RDL 310 extends completely over the first surface of each semiconductor die and/or the filling material. In another example, the first RDL 310 extends partially over the first surface of each semiconductor die and/or the filling material 250.

In an example, traces 330 of the first RDL 310 are electrically coupled to respective bond pads 270 or solder pads associated with each semiconductor die. The traces 330 directly couple at least one semiconductor die to at least one other semiconductor die in the semiconductor die layer 200. Additionally, the traces 330 extend through the vias 260 to the second RDL 320 (FIG. 3) and/or to one or more connection points 280 (FIG. 2).

FIG. 5 illustrates a bottom view of the semiconductor die layer 200 of FIG. 2 according to an example. As shown in FIG. 5, the second RDL 320 is provided on or over a second surface (or a bottom surface) of each semiconductor die. Like the first RDL 310, the second RDL 320 extends completely over the second surface of each semiconductor die and/or the filling material 250. In another example, the second RDL 320 extends partially over the second surface of each semiconductor die and/or the filling material 250.

In an example, traces 330 associated with the second RDL 320 are coupled to various bond pads and/or connection points 280 associated with each semiconductor die. Additionally, the traces 330 extend through the vias 260 and/or are used to electrically couple the first RDL 310 to the second RDL 320. In another example, the traces 330 of the second RDL 320 directly electrically couple at least one semiconductor die to at least one other semiconductor die of the semiconductor die layer 200.

FIG. 6 illustrates a semiconductor package 600 having a multiple semiconductor die layers according to an example. For example, the semiconductor package 600 includes a first semiconductor layer 610 and a second semiconductor layer 620. Each of the first semiconductor die layer 610 and the second semiconductor die layer 620 are similar to the semiconductor layer 200 shown and described with respect to FIG. 2. Although FIG. 6 illustrates a semiconductor package 600 having two semiconductor die layers, the semiconductor package 600 may have fewer than two semiconductor die layers or more than two semiconductor die layers.

In this example, the first semiconductor die layer 610 is stacked on top of the second semiconductor die layer 620. Additionally, the first semiconductor die layer 610 is electrically and/or communicatively coupled to the second semiconductor die layer 620 using various connection points 660. For example, the connection points 660 associated with the first semiconductor die layer 610 are used to directly electrically and/or communicatively couple the first semiconductor die layer 610 to the second semiconductor die layer 620 (e.g., via one or more bond pads associated with the first RDL on the first surface of the second semiconductor die layer 620).

The semiconductor package 600 also includes one or more integrated circuits 630. In an example, the integrated circuits 630 are directly electrically and/or communicatively coupled to the first semiconductor die layer 610 using various connection points 650. For example, the connection points 650 associated with the integrated circuits are coupled to corresponding bond pads on or otherwise associated with the RDL of the first semiconductor die layer 610. In an example, the connection points 650 are bond pads, copper bumps or the like.

As also shown in FIG. 6, the stack of semiconductor die layers is directly coupled to a PCB 640. For example, connection points 660 associated with the second semiconductor die layer 620 are used to directly couple the second semiconductor die layer 620, and/or the entire stack of semiconductor die layers, to the PCB 640 (e.g., without the use or the need for a substrate (e.g., substrate 110 (FIG. 1)).

FIG. 7 illustrates a semiconductor package 700 having multiple semiconductor die layers according to another example. For example, the semiconductor package 700 includes a first semiconductor die layer 710, a second semiconductor die layer 720 and a third semiconductor die layer 730. Each of the first semiconductor die layer 710, the second semiconductor die layer 720 and the third semiconductor die layer are similar to the semiconductor die layer 200 shown and described with respect to FIG. 2. Although FIG. 7 illustrates a semiconductor package 700 having three semiconductor die layers, the semiconductor package 700 may have fewer than three semiconductor die layers or more than three semiconductor die layers.

In this example, the first semiconductor die layer 710 is stacked on top of the second semiconductor die layer 720, which is stacked on top of the third semiconductor die layer 730. Each semiconductor die layer is directly electrically and/or communicatively coupled using various connection points 750 such as previously described.

In this example, the semiconductor package 700 includes one or more passive components 760. In an example, the passive components 760 are directly electrically and/or communicatively coupled to the first semiconductor die layer 710. For example, the passive components 760 are coupled to one or more bond pads and/or traces associated with the first RDL of the first semiconductor die layer 710.

As also shown in FIG. 7, the stack of semiconductor die layers is directly coupled to a PCB 740. For example, connection points 750 associated with the third semiconductor die layer 730 are used to directly couple the third semiconductor die layer 730 and/or the entire stack of semiconductor die layers to the PCB 740 (e.g., without the use or the need for a substrate (e.g., substrate 110 (FIG. 1)).

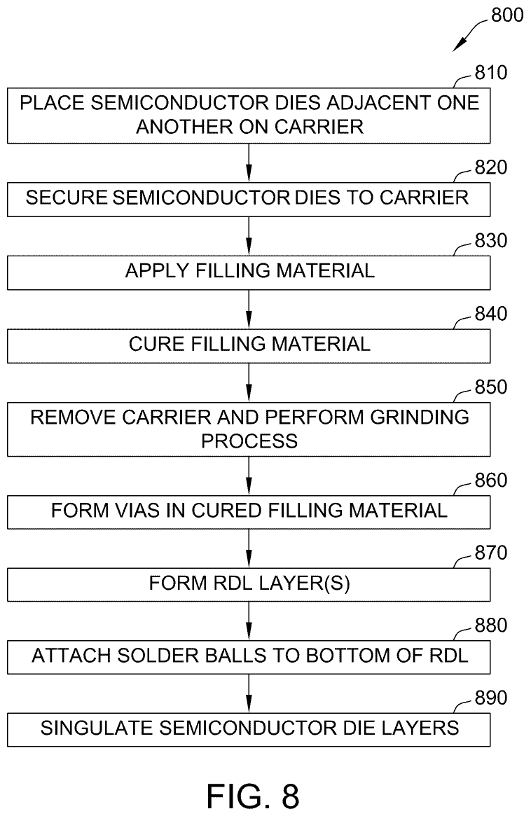

FIG. 8 depicts a method 800 of creating a semiconductor die layer for a semiconductor package according to an example. In an example, the method 800, or portions of the method 800, are used to create or assemble the semiconductor die layer 200 shown and described with respect to FIG. 2.

In an example, the method 800 begins when semiconductor dies are placed (810) adjacent one another on a carrier. In an example, the semiconductor dies are placed on the carrier (or other surface) by a pick and place machine or by another process. When placed on the carrier, the semiconductor dies are arranged in any pattern. For example, the semiconductor dies are arranged in a 2×2 pattern, a 4×4 pattern or any other desired layout.

When the semiconductor dies have been placed on the carrier, the semiconductor dies are secured (820) to the carrier. In an example, the semiconductor dies are secured to the carrier using a bonding material (e.g., tape). A filling material is then applied (830). In an example, the filling material fills in a space that is present between each semiconductor die. For example, the filling material is placed in the spaces between lateral sides of each semiconductor die.

When the filling material has been applied, the filling material is cured (840) which joins the plurality of semiconductor dies together. Upon completion of the curing process, the carrier and the tape is removed and a griding process is performed. In an example, the grinding process is used to help ensure that the semiconductor dies are ready to receive the first and second RDL layers.

Vias are then formed (860) in the cured filling material. In an example, any number of vias are formed in the cured filling material. Additionally, the vias are arranged in any suitable or desired pattern and/or depth.

When the vias have been formed in the cured filling material and the semiconductor dies have been cleaned, RDL layers are formed (870) on a first surface of the semiconductor dies and a second surface of the semiconductor dies. In an example, any suitable process of forming an RDL layer may be used.

When the RDL layers have been formed, solder balls or other connection points are attached to the bottom RDL. The semiconductor dies are then singulated (890) to form individual semiconductor die layers.

Based on the above, examples of the present disclosure describe a semiconductor package, comprising: a first semiconductor die; a second semiconductor die adjacent to the first semiconductor die; a filling material provided between the first semiconductor die and the second semiconductor die and joining a first lateral side of the first semiconductor die to a second lateral side of the second semiconductor die; a first redistribution layer (RDL) formed on top surfaces of the first semiconductor die and the second semiconductor die; and a second RDL formed on bottom surfaces of the first semiconductor die and the second semiconductor die. In an example, the semiconductor package also includes a plurality of solder balls provided on the second RDL that enable the semiconductor package to be connected to at least one of a printed circuit, a substrate, and a second semiconductor package. In an example, the semiconductor package also includes a plurality of vias disposed within the filling material. In an example, at least one via of the plurality of vias includes a trace that electrically couples the first RDL and the second RDL. In an example, the filling material is an epoxy filling material. In an example, one or more traces associated with the first RDL communicatively couples the first semiconductor die and the second semiconductor die. In an example, the semiconductor package also includes a plurality of bond pads provided on the top surface of each of the first semiconductor die and the second semiconductor die and beneath the first RDL, that enable communications between the first and second semiconductor dies and the first RDL. In an example, the first semiconductor die is a first type of semiconductor die and the second semiconductor die is a second type of semiconductor die that is different than the first semiconductor die.

Examples also describe a semiconductor package, comprising: a first semiconductor die layer comprising: a first semiconductor die adjacent a second semiconductor die and joined to the second semiconductor die by a first filling material; a first redistribution layer (RDL) on first surfaces of the first semiconductor die and the second semiconductor die; and a second RDL on second surfaces of the first semiconductor die and the second semiconductor die; and a second semiconductor die layer stacked on top of the first semiconductor die layer, the second semiconductor die layer comprising: a third semiconductor die adjacent a fourth semiconductor die and joined to the fourth semiconductor die by a second filling material; a third RDL on first surfaces of the third semiconductor die and the fourth semiconductor die; and a fourth RDL on second surfaces of the third semiconductor die and the fourth semiconductor die. In an example, the semiconductor package also includes a plurality of solder balls provided on the fourth RDL, the plurality of solder balls electrically coupling the second semiconductor die layer to the first die layer. In an example, the semiconductor package also includes a plurality of solder balls provided on the second RDL, the plurality of solder balls electrically coupling the first semiconductor die layer to a printed circuit board (PCB). In an example, the semiconductor package also includes at least one via in each of the first filling material and the second filling material, the at least one via enabling electrical communication between the first and second RDLs and/or the third and fourth RDLs. In an example, the semiconductor package also includes an integrated circuit electrically coupled to the third RDL. In an example, the semiconductor package also includes a passive component electrically coupled to the third RDL. In an example, the semiconductor package also includes further comprising a first set of traces associated with the first RDL that communicatively couple the first semiconductor die and the second semiconductor die, and a second set of traces associated with the third RDL that communicatively couple the third semiconductor die and the fourth semiconductor die.

Examples also describe a method for assembling a semiconductor die layer for a semiconductor package, the method comprising: placing a plurality of semiconductor dies side-by-side on a carrier; causing a filling material to flow between each of the plurality of semiconductor dies; curing the filling material to join each of the plurality of semiconductor dies to at least one other semiconductor die of the plurality of semiconductor dies; removing the joined semiconductor dies from the carrier; and forming one or more vias in the filling material between each of the plurality of semiconductor dies. In an example, the method also includes forming a first redistribution layer (RDL) on a first side of the joined semiconductor dies and a second RDL on a second side of the joined semiconductor dies. In an example, the method also includes attaching a plurality of solder balls on the second RDL. In an example, at least one trace of the first RDL is coupled to a bond pad of at least one semiconductor die of the plurality of semiconductor dies. In an example, the one or more vias in the filling material electrically connect traces in the first RDL with traces in the second RDL.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a first semiconductor die;
a second semiconductor die adjacent to the first semiconductor die;
a filling material provided between the first semiconductor die and the second semiconductor die and joining a first lateral side of the first semiconductor die to a second lateral side of the second semiconductor die;
a first redistribution layer (RDL) formed on top surfaces of the first semiconductor die and the second semiconductor die; and
a second RDL formed on bottom surfaces of the first semiconductor die and the second semiconductor die.

2. The semiconductor package of claim 1, further comprising a plurality of solder balls provided on the second RDL that enable the semiconductor package to be connected to at least one of a printed circuit, a substrate, and a second semiconductor package.

3. The semiconductor package of claim 1, further comprising a plurality of vias disposed within the filling material.

4. The semiconductor package of claim 3, wherein at least one via of the plurality of vias includes a trace that electrically couples the first RDL and the second RDL.

5. The semiconductor package of claim 1, wherein the filling material is an epoxy filling material.

6. The semiconductor package of claim 1, wherein one or more traces associated with the first RDL communicatively couples the first semiconductor die and the second semiconductor die.

7. The semiconductor package of claim 1, further comprising a plurality of bond pads provided on the top surface of each of the first semiconductor die and the second semiconductor die and beneath the first RDL, that enable communications between the first and second semiconductor dies and the first RDL.

8. The semiconductor package of claim 1, wherein the first semiconductor die is a first type of semiconductor die and the second semiconductor die is a second type of semiconductor die that is different than the first semiconductor die.

9. A semiconductor package, comprising:
a first semiconductor die layer comprising:
a first semiconductor die adjacent a second semiconductor die and joined to the second semiconductor die by a first filling material;
a first redistribution layer (RDL) on first surfaces of the first semiconductor die and the second semiconductor die; and
a second RDL on second surfaces of the first semiconductor die and the second semiconductor die; and
a second semiconductor die layer stacked on top of the first semiconductor die layer, the second semiconductor die layer comprising:
a third semiconductor die adjacent a fourth semiconductor die and joined to the fourth semiconductor die by a second filling material;
a third RDL on first surfaces of the third semiconductor die and the fourth semiconductor die; and
a fourth RDL on second surfaces of the third semiconductor die and the fourth semiconductor die.

10. The semiconductor package of claim 9, further comprising a plurality of solder balls provided on the fourth RDL, the plurality of solder balls electrically coupling the second semiconductor die layer to the first die layer.

11. The semiconductor package of claim 9, further comprising a plurality of solder balls provided on the second RDL, the plurality of solder balls electrically coupling the first semiconductor die layer to a printed circuit board (PCB).

12. The semiconductor package of claim 9, further comprising at least one via in each of the first filling material and the second filling material, the at least one via enabling electrical communication between the first and second RDLs and/or the third and fourth RDLs.

13. The semiconductor package of claim 9, further comprising an integrated circuit electrically coupled to the third RDL.

14. The semiconductor package of claim 9, further comprising a passive component electrically coupled to the third RDL.

15. The semiconductor package of claim 9, further comprising a first set of traces associated with the first RDL that communicatively couple the first semiconductor die and the second semiconductor die, and a second set of traces associated with the third RDL that communicatively couple the third semiconductor die and the fourth semiconductor die.

16. A method for assembling a semiconductor die layer for a semiconductor package, the method comprising:
placing a plurality of semiconductor dies side-by-side on a carrier;
causing a filling material to flow between each of the plurality of semiconductor dies;
curing the filling material to join each of the plurality of semiconductor dies to at least one other semiconductor die of the plurality of semiconductor dies;
removing the joined semiconductor dies from the carrier; and
forming one or more vias in the filling material between each of the plurality of semiconductor dies.

17. The method of claim 16, further comprising forming a first redistribution layer (RDL) on a first side of the joined semiconductor dies and a second RDL on a second side of the joined semiconductor dies.

18. The method of claim 17, further comprising attaching a plurality of solder balls on the second RDL.

19. The method of claim 17, wherein at least one trace of the first RDL is coupled to a bond pad of at least one semiconductor die of the plurality of semiconductor dies.

20. The method of claim 17, wherein the one or more vias in the filling material electrically connect traces in the first RDL with traces in the second RDL.
